(19) United States
(12) Patent Application Publication
(10) Pub. No.: US 2022/0051830 A1
(43) Pub. Date: Feb. 17, 2022

(54) DATA COMMUNICATION CABLE AND METHOD OF MANUFACTURING SUCH CABLE

(71) Applicant: MAS Innovation (Private) Limited, Battaramulla (LK)

(72) Inventors: Raweendra Randeni Kumara THALAGAHA GEDARA, Colombo (LK); Kosalasiri JAYASUNDARA, Colombo (LK); Liyana Arachchige Don Krishan Chaminda WEERAWANSA, Malwana (LK); Nalantha Priyaranga DE ALWIS, Malwana (LK)

(21) Appl. No.: 17/312,439

(22) PCT Filed: Dec. 26, 2019
(86) PCT No.: PCT/SG2019/050645

§ 371 Date: Jun. 10, 2021

(30) Foreign Application Priority Data
Dec. 28, 2018 (SG) 10201811791W

(51) Int. Cl. H01B 7/06; H01B 7/08; H01B 13/008; H01B 11/00

(52) U.S. Cl. CPC H01B 7/06; H01B 11/002; H01B 13/008; H01B 7/083

(57) ABSTRACT

The present invention generally relates to a data communication cable (100) comprising: a set of elongated bodies (102) each formed from an elastic material and having an unextended free length; and for each elongated body (102), a set of conductive wires (104) disposed along the elongated body (102), such that each conductive wire (104) is extendable to more than the free length of the elongated body (102), wherein at least one conductive wire (104) is configured for communicating data between electronic devices; and wherein the conductive wires (104) are extendable in response to extension of the elongated body (102), such that the extended data communication cable (100) remains useable for said data communication between the electronic devices.

### CROSS REFERENCE TO RELATED APPLICATION(S)

The present invention claims the benefit of Singapore Patent Application No. 10201811791W filed on 28 Dec. 2018, which is incorporated in its entirety by reference herein.

### TECHNICAL FIELD

The present invention generally relates to a data communication cable. More particularly, the present invention describes various embodiments of a data communication cable and a method of making the data communication cable.

### BACKGROUND

Many electronic devices, including computers, laptops, and mobile phones, require the use of data communication cables for communicating or transferring data between them. The most common example of a data communication cable is the USB cable. However, users often must purchase multiple cables of varying lengths to suit their different purposes. For example, a user may use a shorter cable connecting a mobile phone to a laptop, but a longer cable connecting the mobile phone to a power socket. This results in many cables lying around and cluttering the user's home.

Therefore, in order to address or alleviate at least the aforementioned problem or disadvantage, there is a need to provide an improved data communication cable.

### SUMMARY

According to a first aspect of the present invention, there is a data communication cable comprising: a set of elongated bodies each formed from an elastic material and having an unextended free length; and for each elongated body, a set of conductive wires disposed along the elongated body, such that each conductive wire is extendable to more than the free length of the elongated body, wherein at least one conductive wire is configured for communicating data between electronic devices; and wherein the conductive wires are extendable in response to extension of the elongated body, such that the extended data communication cable remains useable for said data communication between the electronic devices.

According to a second aspect of the present invention, there is a method of making a data communication cable, the method comprising: forming a set of elongated bodies from an elastic material, each elongated body having an unextended free length; and disposing, for each elongated body, a set of conductive wires along the elongated body, such that each conductive wire is extendable to more than the free length of the elongated body, wherein at least one conductive wire is configured for communicating data between electronic devices; and wherein the conductive wires are extendable in response to extension of the elongated body, such that the extended data communication cable remains useable for said data communication between the electronic devices.

A data communication cable according to the present invention is thus disclosed herein. Various features, aspects, and advantages of the present invention will become more apparent from the following detailed description of the embodiments of the present invention, by way of non-limiting examples only, along with the accompanying drawings.

### BRIEF DESCRIPTION OF THE DRAWINGS

FIG. 1A and FIG. 1B are illustrations of data communication cable, in accordance with embodiments of the present invention.

FIG. 2 is an illustration of the data communication cable showing yarn loops for the conductive wires, in accordance with embodiments of the present invention

FIG. 3 and FIG. 4 are illustrations of the data communication cable having four elongated bodies with conductive wires, in accordance with embodiments of the present invention.

FIG. 5A to FIG. 5C are illustrations of the data communication cable showing foldability of the four elongated bodies, in accordance with embodiments of the present invention.

FIG. 6 is a cross-sectional illustration of a conductive wire, in accordance with embodiments of the present invention.

FIG. 7 is an illustration of an electronic positive feeding mechanism for forming the conductive wires, in accordance with embodiments of the present invention.

FIGS. 8 and 9 are illustrations for calculation of the inter-wire length tolerance of the conductive wires, in accordance with embodiments of the present invention.

### DETAILED DESCRIPTION

In the present invention, depiction of a given element or consideration or use of a particular element number in a particular figure or a reference thereto in corresponding descriptive material can encompass the same, an equivalent, or an analogous element or element number identified in another figure or descriptive material associated therewith. The use of “I” in a figure or associated text is understood to mean “and/or” unless otherwise indicated. The recitation of a particular numerical value or value range herein is understood to include or be a recitation of an approximate numerical value or value range. The term “set” is defined as a non-empty finite organization of elements that mathematically exhibits a cardinality of at least one (e.g. a set as defined herein can correspond to a unit, singlet, or single-element set, or a multiple-element set), in accordance with known mathematical definitions. As used herein, the terms “first”, “second”, and “third” are used merely as labels or identifiers and are not intended to impose numerical requirements on their associated terms.

For purposes of brevity and clarity, descriptions of embodiments of the present invention are directed to a data communication cable, in accordance with the drawings. While aspects of the present invention will be described in conjunction with the embodiments provided herein, it will be understood that they are not intended to limit the present invention to these embodiments. On the contrary, the present invention is intended to cover alternatives, modifications and equivalents to the embodiments described herein, which are included within the scope of the present invention as defined by the appended claims. Furthermore, in the following detailed description, specific details are set forth in order to provide a thorough understanding of the present invention. However, it will be recognized by an individual having ordinary skill in the art, i.e. a skilled person, that the present invention may be practiced without specific details, and/or with multiple details arising from combinations of aspects of particular embodiments. In a number of instances, well-known systems, methods, procedures, and components have not been described in detail so as to not unnecessarily obscure aspects of the embodiments of the present invention.

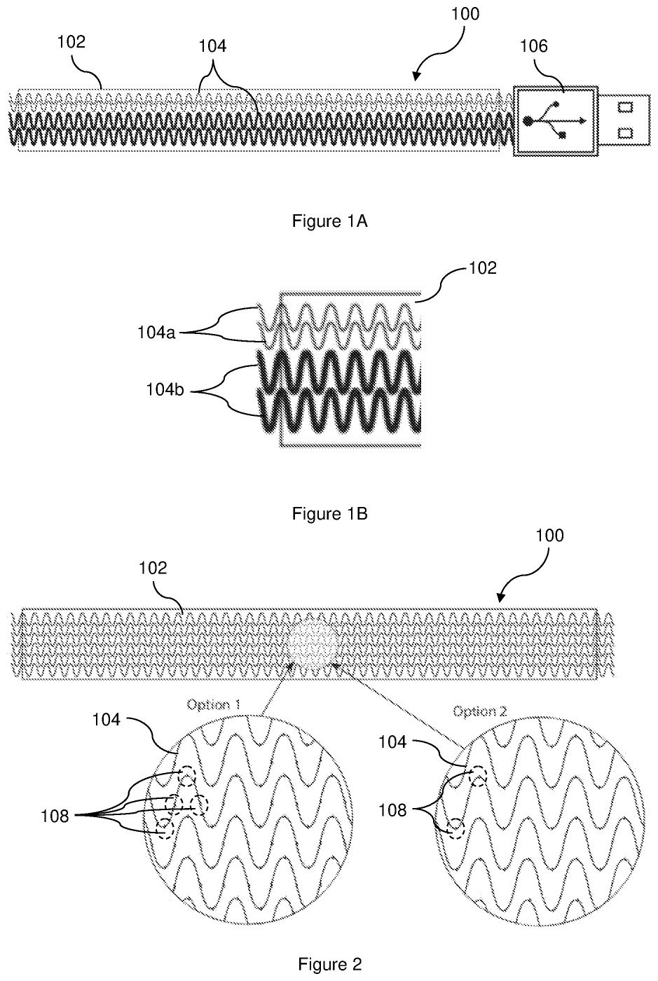

In representative or exemplary embodiments of the present invention, there is a data communication cable 100 as illustrated in FIG. 1A. The data communication cable 100 includes a set of, i.e. one or more, elongated bodies 102. Each elongated body 102 is formed from an elastic material and having an unextended free length. The data communication cable 100 further includes, for each elongated body 102, a set of, i.e. one or more, conductive wires 104 disposed along the elongated body 102, such that each conductive wire 104 is extendable to more than the free length of the elongated body 102. At least one conductive wire 104 is configured for communicating data between electronic devices, and the conductive wires 104 are extendable in response to extension of the elongated body 102, such that the extended data communication cable 100 remains useable for said data communication between the electronic devices.

In various embodiments of the present invention, there is a method of making the data communication cable 100. The method includes a step of forming the set of elongated bodies 102 from an elastic material. The method further includes a step of disposing, for each elongated body 102, the set of conductive wires 104 along the elongated body 102. The conductive wires 104 may be attached to and disposed along the elongated body 102 during forming of the elongated body 102 with the elastic material, or after the elongated body 102 has been formed. Additionally, the method may include joining the elongated bodies 102 along their respective longitudinal edges such that the elongated bodies 102 are foldable along the longitudinal edges, as described further below.

In some embodiments, the data communication cable 100 is used for connection between two electronic devices, such as computers. When the data communication cable 100 is connected between both electronic devices, at least one conductive wire 104 is configured for communicating data, such as including computer/electronic signals, between the electronic devices. Thus, the data communication cable 100 is useable for data communication between the electronic devices when connected therebetween. The electronic devices may include, but are not limited to, computers, laptops, tablets, mobile phones, and the like. Additionally, the conductive wires 104 are extendable in response to extension of the elongated body 102, such that the extended data communication cable 100 remains useable for said data communication, such as high speed and/or low speed data transfer, between the electronic devices.

In some embodiments, the data communication cable 100 further includes at least one data interface connector 106 connected to one or both ends of the elongated bodies 102. The data interface connector may be, but is not limited to, a USB or HDMI connector. For example as shown in FIG. 1A, the data communication cable 100 includes one data interface connector 106 connected to one end of the elongated body 102. Additionally, the conductive wires 104 in the elongated body 102 may be of one or more types, so that the data communication cable 100 can be configured for performing one or more functions by using one or more types of conductive wires 104. Such functions of the data communication cable 100 include, but are not limited to, high speed data transfer, low speed data transfer, and power transmission. For example as shown in FIG. 1B, the data communication cable 100 includes two types of conductive wires 104, namely conductive wires 104a for data transfer and conductive wires 104b for power transmission. The conductive wires 104a for data transfer may include different types for data transfer at different speeds, e.g. high speed and low speed data transfers. The conductive wires 104a may alternatively be of a single type for either high speed or low speed data transfer.

Each of the one or more elongated bodies 102 of the data communication cable 100 is made of an elastic material which has an appropriate Young's modulus so that it is elastic/stretchable. In some embodiments, the elastic material is an elastic fabric material such as, but not limited to, spandex having a suitable Young's modulus. The elastic fabric material and may be knitted or woven with various types of yarns. The stretch/elasticity may range from 5% to 250% and this can be achieved such as by varying the Young's modulus (e.g. between 1 and 1000 N), changing the filament/fibre count of the elastic fabric material (e.g. rubber count for spandex), yarn, structure, and knitting method. The elongated body 102 may include other fabric materials or yarns to provide other properties, such as breathability and moisture transfer.

The conductive wires 104 are incorporated, e.g. by knitting/stitching/weaving, within the elastic material of the elongated body 102, so as to enable the conductive wires 104 to stretch and retain their shape, as well as to provide durability to the conductive wires 104. The conductive wires 104 or pathways are disposed or laid along the elongated body 102 so that the data communication cable 100 is extendable/stretchable for use with electronic devices separated by various distances. Incorporating the conductive wires 104 within the elongated body 102 achieves properties such as stretchability, drapability, and wash reliability.

In some embodiments as shown in FIG. 1A and FIG. 1B, for each elastic elongated body 102, the conductive wires 104 are arranged parallel to one another. Additionally, the conductive wires 104 are arranged in a sinusoidal/wavy/serpentine arrangement along the respective elongated body 102. The sinusoidal/wavy/serpentine arrangement enables each conductive wire 104 to stretch in both directions along the length of the elongated body 102 while residing within the elastic structure of the elongated body 102. Alternatively, the conductive wires are arranged to be curved warp-wise to achieve extendibility/stretchability properties. Yet alternatively, the conductive wires 104 are wound around yarns of the respective elongated body 102 to obtain a spiral-type arrangement and achieve extendibility/stretchability properties.

In some embodiments as shown in FIG. 2, the elongated body 102 is formed of an elastic fabric material and the conductive wires 04 are arranged sinusoidally and parallel to one another. Specifically, each conductive wire 104 is held or stitched to the elastic fabric material of the elongated body 102 by yarn loops 108. There are two options to attach the conductive wires 104 to the elongated body 102 using the yarn loops 108, although it will be appreciated that there may be other options or configurations of doing so. Using yarn loops 108 to stitch the conductive wires 104 allows for the stretchability and consistency throughout the conductive wires 104, and also allows a better packing of the conductive wires 104 within the elongated body 102.

In Option 1 as shown in FIG. 2, each cycle of the sinusoidal arrangement of the conductive wires 104 is stitched to the elongated body 102 by four yarn loops 108. This allows the elongated body 102 to hold the conductive wires 104 better and more firmly within the elongated body 102. The elongated body 102 can thus maintain adhesion of the conductive wires 104 the surface of the elongated body 102 even if the elongated body 102 has a very low Young's modulus. Using four yarn loops 108 per sinusoidal cycle is more suitable if the sinusoidal cycle size is larger compared to the diameter of the conductive wire 104.

In Option 2 as shown in FIG. 2, each cycle of the sinusoidal arrangement of the conductive wires 104 is stitched to the elongated body 102 by two yarn loops 108. This allows for more flexibility in holding the conductive wires 104 to the elongated body 102. Although it is more difficult for the elongated body 102 to keep the conductive wires 104 held firmly, using two yarn loops 108 per sinusoidal cycle is suitable if the elongated body 102 has a high Young's modulus as the elastic structure of the elongated body 102 provides a stronger force to hold the conductive wires 104. Using two yarn loops 108 per sinusoidal cycle is also more suitable if the sinusoidal cycle size is smaller compared to the diameter of the conductive wire 104.

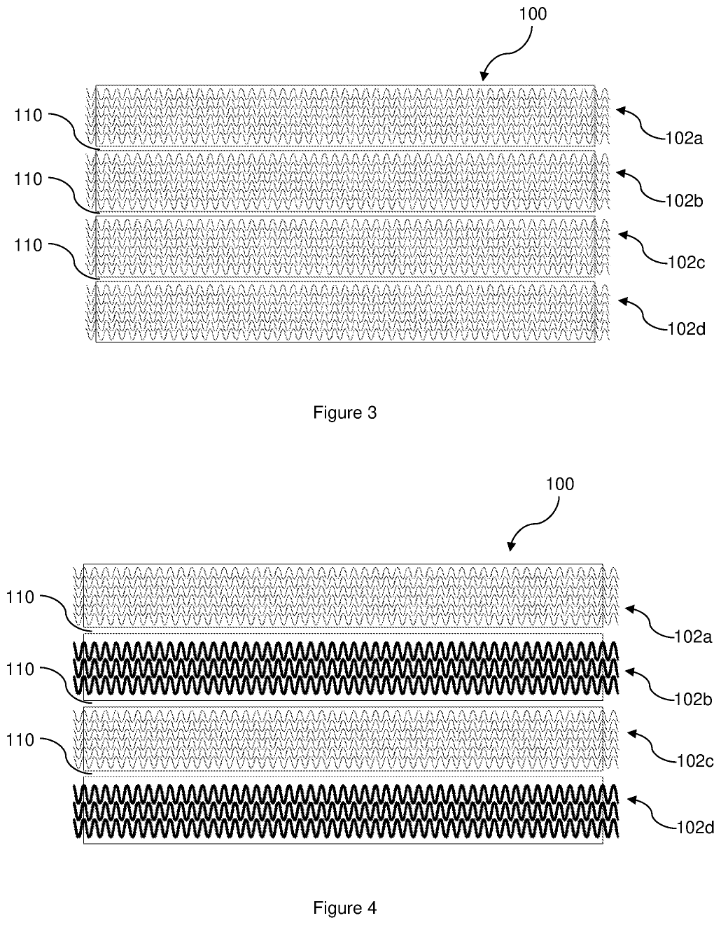

In some embodiments as shown in FIG. 1, the data communication cable 100 includes one elongated body 102. In some other embodiments, the data communication cable 100 includes two or more elongated bodies 102 adjacently joined together along their respective longitudinal edges 110. In one embodiment as shown in FIG. 3, the data communication cable 100 includes four elongated bodies 102a-d adjacently joined together along their respective longitudinal edges 110. The conductive wires 104 of the elongated bodies 102a-d are all parallel to one another and disposed along the elongated bodies 102a-d in an extendable arrangement, such as sinusoidal/wavy/serpentine.

As mentioned above, each elongated body 102 may have one or more types of conductive wires 104 for performing different functions, such as data transfer and power transmission. In one embodiment as shown in FIG. 3, the data communication cable 100 includes four elongated bodies 102a-d, each elongated body 102a-d having the same type of conductive wires 104 and configured for the same data communication function, such as high speed and low speed data transfer.

In another embodiment as shown in FIG. 4, the data communication includes four elongated bodies 102a-d, at least one elongated body 102a-d being configured for data communication and at least one elongated body 102a-d being configured for power transmission. For example, the first and third elongated bodies 102ac are configured for data transfer, such as high speed and low speed data transfer, and the second and fourth elongated bodies 102bd are configured for power transmission. Each elongated body 102a-d is thus configured for performing one function by using the same type of conductive wires 104. However, it may be possible that each elongated body 102a-d is configured for performing different functions by using different types of conductive wires 104.

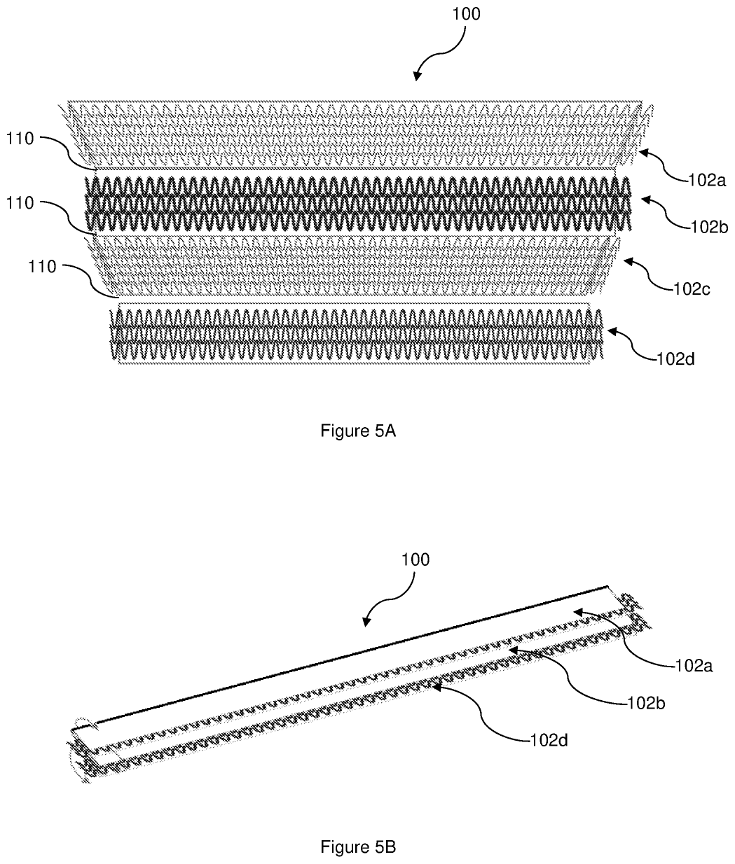

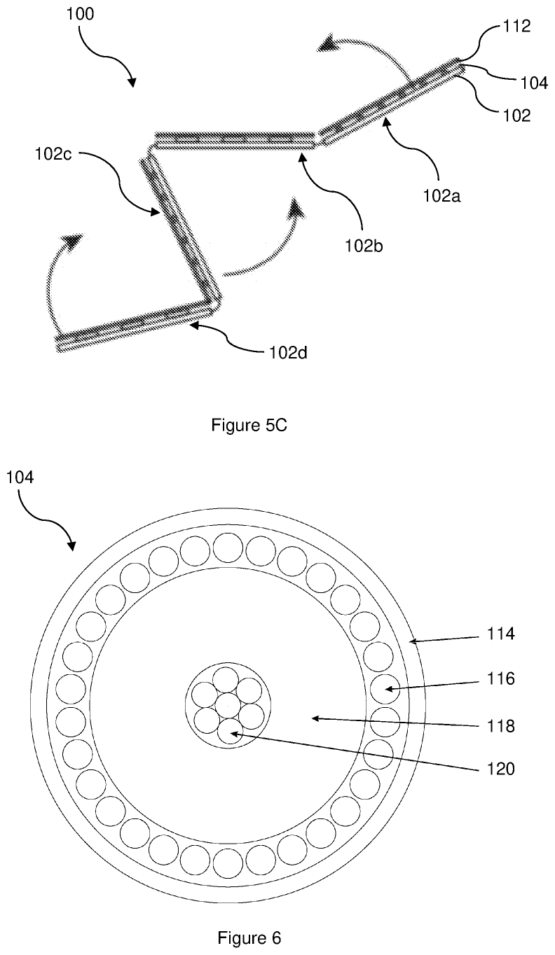

Further with reference to FIG. 5A to FIG. 5C, the four elongated bodies 102a-d of the data communication cable 100 are foldable along the respective longitudinal edges 110 so that the elongated bodies 102a-d are stackable together for the data communication cable to achieve a thin form factor. Although the data communication cable is shown to have four elongated bodies 102a-d, it will be appreciated that the data communication cable 100 can have any number, e.g. two or more, of elongated bodies 102 that are foldable in a similar manner. The foldable/bendable structure of the data communication cable 100 allows the total number of conductive wires 104 to be shorter in width collectively, while achieving the extendability/stretchability properties and other elastic properties described above. The data communication cable 100 can thus have a large number of conductive wires 104 within a narrower width, especially when the data communication cable 100 is used in some applications where there is space constraint.

In some embodiments as shown in FIG. 5C, the data communication cable 100 includes four elongated bodies 102 that are foldable together, and respective layers of conductive wires 104 are disposed along each elongated body 102. The data communication cable may additionally include an exterior shielding layer 112 for each elongated body 102, such that the conductive wires 104 are interposed between the elongated body 102 and the exterior shielding layer 112. The exterior shielding layer 112 is formed from an elastic material, such as an elastic fabric material which may be made from or includes conductive yarns. The exterior shielding layers 112 are configured for countering interference to operation or functionality of the data communication cable 100. The exterior shielding layers 112 enhance the peak high speed data transfer frequency by supplying an exterior shield, in addition to any shielding around each conductive wire 104 to shield the conductive wires 104 from outside noise. Thus, the conductive wires 104 can be shielded by the exterior shielding layers 112 to achieve mechanical stability and better electrical shielding. Sandwiching the conductive wires 104 between the elongated body 102 and the exterior shielding layer 112 also allows the conductive wires 104 to be hidden within the data communication cable 100. This reduces the external interference and minimizes visibility of the conductive wires 104 from the outside, thus mitigating risk of damage to the conductive wires 104 during use of the data communication cable 100.

Each conductive wire 104 may include an arrangement of one or more conductive strands. The arrangement of the conductive strands may be coaxial, twisted, twisted pairs, shielded, or like optical fibre cables. The conductive wires 104 may be made using textile grade wires to achieve suitable drapability and strength to withstand stress and strain resulting from multiple stretching and bending actions on the data communication cable 100. The conductive wires 104 may be formed from metallic materials such as aluminium, copper, zinc, silver, gold, or any combination/alloy thereof. Each conductive wire 104 may have a tin coating to reduce corrosion, especially when the data communication cable 100 is subject to washing. For example, the data communication cable 100 may be used in garments, such as smart garments having sensor devices, and the garments are subject to washing. Each conductive wire 104 may have a coating, such as a fabric coating, made of or including conductive yarns to reduce external noise and to provide shielding from inter-wire noise. Each conductive wire 104 may have an insulation coating made of or including a wire insulation material, such as polyurethane (PU), nylon, fluorinated ethylene propylene (FEP), Teflon, silicon, or any combinations thereof.

With reference to FIG. 6, each conductive wire 104 may include an outer insulated layer 114, a shielding layer 116, an inner insulated layer 118, and a core 120 having an arrangement of conductive strands/filaments/lines. The conductive wires 104 may be obtained from commercially available sources, such as twisted and/or shielded cables originally used for high speed data transfer. Each conductive wire 104 should have adequate high speed data transfer capability of their own to enable the final product, i.e. the data communication cable 100 after laying the conductive wires 104 along the elastic elongated body 102, to transfer high speed data.

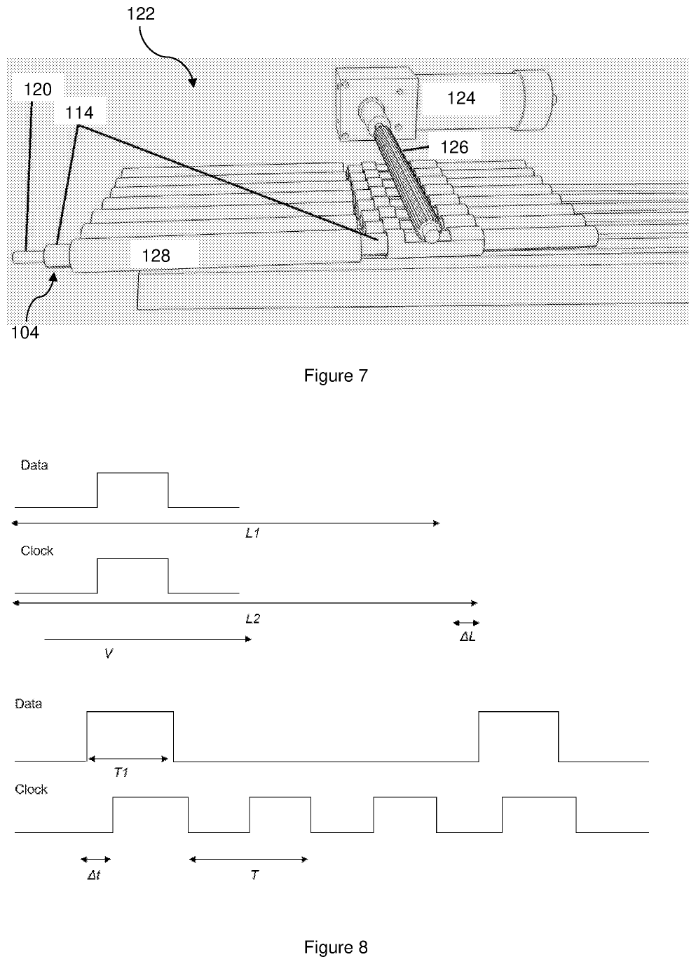

The conductive wires 104 in the data communication cable 100 have substantially the same, or preferably identical, lengths having a inter-wire length tolerance, i.e. the difference in lengths among the conductive wires 104, is very low in the range of 1 to 2 mm. The conductive wires 104 may be formed using an electronic positive feeding mechanism 122 as shown in FIG. 7 to achieve the low inter-wire length tolerance. Conventionally, the limitations and tolerances of textile processing machines can only achieve inter-wire length tolerances in the range of 2 to 5 mm which is not suitable for data communication. The electronic positive feeding mechanism 122 includes an electronic positive feeder 124, a tooth rod 126, and a plurality of wire feeding tubes 128 wherein the conductive wires 104 are passed through. For purpose of brevity, operation of the electronic positive feeding mechanism 122 is not further described but such operation will be readily understood by the skilled person.

The low inter-wire length tolerance is important for high speed data transfer. As the data communication cable 100 includes multiple conductive wires 104, data is communicated through the conductive wires 104 at the same time. Minimizing the inter-wire length tolerance is necessary to achieve shorter delay times among the conductive wires 104. Ideally, the data should communicate through every conductive wire 104 in the same duration so as to mitigate risk of the data being compromised or corrupted.

For two parallel conductive wires 104 to communicate or transfer data properly, the data sent in a single clock cycle should reach the destination within a time difference of less than a quarter of a clock cycle. The clock cycle is one aspect of a computer processor's performance. In a computer, the clock cycle is the cycle of time between two adjacent pulses of the oscillator that sets the tempo of the computer processor, as will be readily understood by the skilled person.

For example, the data communication cable 100 is used as a HDMI cable. A 4K video transmission at a frame rate of 60 FPS (frame rate), 16-bit colour depth, and 4:2:0 chroma sampling requires a data transfer rate of 17.82 Gbps (gigabits per second). This data transfer rate is equivalent to a data transfer rate per data channel of 5.94 Gbps as the HDMI cable has three data channels. When the handshaking data and header data are also considered, the required data transfer rate would be even higher. For such data transfer using a 6 GHz computer processor, a single clock cycle is equivalent to 0.167 ns (nanosecond). At such data communication speeds, the inter-wire length tolerance is calculated to be very low in the range of 1 to 2 mm. Therefore, it is necessary to minimize the inter-wire length tolerance, such as by using the electronic positive feeding mechanism 122 to form the conductive wires 104.

The low inter-wire length tolerance of 1 to 2 mm is typical for common computer data cables which usually range from 100 to 1000 mm. The tolerance may be governed by various PCB or IPC electronics standards. Typically, up to a quarter of time difference in one clock cycle between two parallel conductive wires 104 or data paths can be allowed. For a 4 GHz data transmission, each clock cycle is 0.25 ns and if the data arrives less than 0.0625 ns apart at the receiving end, they could, theoretically, be valid. For a trace or length of approximately 1000 mm, this translates to an inter-wire length tolerance of approximately 18 mm. However, if the processing PCBs are less tolerant such as in the present invention, the PCB would reject the data or treat the data as corrupted for anything more than 5%, as a rule of thumb, of one clock cycle, and this translates to a lower inter-wire length tolerance of approximately 1 to 2 mm. Use of this inter-wire length tolerance is thus for compliance to application hardware and software standards.

The description below shows some calculations on how the tolerance of 1 to 2 mm is derived, with reference to FIG. 8. L1 represents the data signal travelling length per second; L2 represents the clock signal travelling length per second; ΔL represents the length tolerance due to length difference; T represents the cycle time; V represents the travelling speed; and C represents the processor speed, such as 4 GHz or 8 GHz.

$$\begin{matrix}Δ t < T 1 & [ Expression 1 ] \\ Δ t < \frac{T}{2} & [ Expression 2 ] \\ T = \frac{1}{f} & [ Expression 3 ] \\ Δ t < \frac{1}{2 f} & [ Expression 4 ] \\ V = \frac{L}{t} & [ Expression 5 ] \\ Δ t = \frac{Δ L}{V} & [ Expression 6 ]\end{matrix}$$

The current travelling speed V is assumed to be the speed of light, which is approximately 300,000,000 m/s, resulting in Expression 7.

$$\begin{matrix}Δ t = \frac{Δ L}{3 \times 1 {0}^{8}} & [ Expression 7 ] \\ T = \frac{1}{C \times 1 {0}^{9}} & [ Expression 8 ]\end{matrix}$$

For half pulse, Expression 8 is halved to become Expression 9.

$$\begin{matrix}\frac{T}{2} = \frac{1}{2 C \times 1 {0}^{9}} & [ Expression 9 ] \\ Δ {t}_{max} = \frac{1}{2 C \times 1 {0}^{9}} & [ Expression 10 ]\end{matrix}$$

For safe communication, Δt is kept at half of the maximum, thus changing Expression 10 to Expression 11. Combining Expressions 7 and 11 results in Expression 12.

$$\begin{matrix}Δ {t}_{max} = \frac{1}{4 C \times 1 {0}^{9}} & [ Expression 11 ] \\ Δ {L}_{max} = \frac{3 \times 1 {0}^{8}}{4 C \times 1 {0}^{9}} & [ Expression 12 ]\end{matrix}$$

For a processor speed of 4 GHz, the maximum length tolerance is calculated to be approximately 18 mm. For a processor speed of 8 GHz, the maximum length tolerance is calculated to be approximately 9 mm.

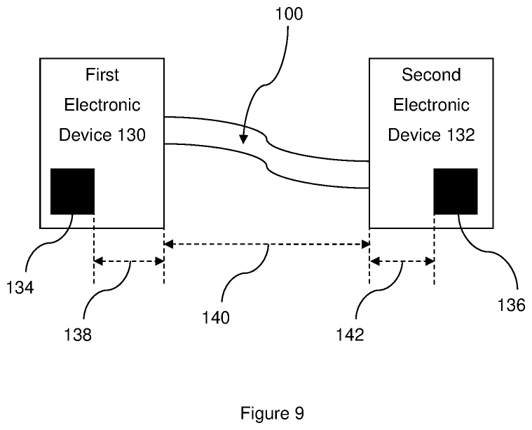

With reference to FIG. 9, the data communication cable 100 may be connected between a first electronic device 130 and a second electronic device 132. The electronic devices 130,132 may be computers having circuits or PCBs 134,136 respectively. As mentioned above, the maximum length tolerance is approximately 9 mm for an 8 GHz processor speed. However, the maximum length tolerance refers to the chip-to-chip total tolerance and a large part of the length tolerance is attributed to PCB path tolerance. This PCB path tolerance is approximately 2 to 4 mm for each electronic device 130,132. Specifically, the PCB path tolerance 138 for the first electronic device 130 refers to the tolerable length difference between the first PCB 134 of the first electronic device 130 and one end of the data communication cable 100, and the PCB path tolerance 142 for the second electronic device 132 refers to the tolerable length difference between the second PCB 136 of the second electronic device 132 and the other end of the data communication cable 100. The remaining length tolerance is attributed to the conductive wire length tolerance 140 of the conductive wires 104 which is approximately 1 to 2 mm.

The data communication cable 100 described herein is thus formed by incorporating multiple parallel conductive wires 104, such as in a sinusoidal/wavy/serpentine arrangement, into elastic elongated bodies 102 such that the data communication cable 100 can retain its shape (i.e. resilience), enable stretchability, and washability while retaining the data communication property, particularly for high speed data transfer.

The durability of the data communication cable 100 enables it to withstand higher numbers of force cycles, stretch cycles, bend cycles, and moisture transfer. This durability is achieved by the conductive wires 104 held firmly on the elastic material of the elongated body 102, making the conductive wires 104 more reliable than regular cables. Due to the property that each conductive wire 104 or pathway is held firm and with the support structure of the elastic material of the elongated body 102, the conductive wires 104 are more reliable than regular parallel straight conductive wires.

The data communication cable 100 is useable for various applications of data communication between two electronic devices. For example, the data communication cable 100 may be used as a USB cable connecting between two computers, an input cable connecting between a gaming device and a computer, a HDMI cable connecting between a computer and a display monitor device, or an Ethernet or PoE (Power over Ethernet) cable connecting between a computer and a RJ45 network port. The data communication cable 100 provides better durability and stretchability properties, and can advantageously be adapted for varying lengths to suit different purposes. For example, the user may use the data communication cable 100 connecting a mobile phone to a laptop. If the user wants to use the same data communication cable 100 to connect the mobile phone to a power socket, he can extend the data communication cable 100 to do so. This advantageously obviates the need to have many cables which would clutter the user's home.

The data communication cable 100 is also robust enough for use with other fabrics/garments/soft goods. One application of the data communication cable 100 is for high speed data transfer in soft goods, such as car seats, eyewear, and the like. The data communication cable 100 may have non-wearable applications which prefer either flexibility or stretchability. For example, the data communication cable 100 can be used in aircraft wiring for data communication, soft robots, or conductors transmitting data through joints.

Another application of the data communication cable 100 is in garments, particularly smart garments having electronic devices such as sensors. The data communication cable 100 can be bonded to the surface of the garment material by using bonding means such as polyurethane film or by melting yarns within elastic material of the data communication cable 100. Such bonding means allow the data communication cable 100 to be easily installed and attached to the garment as well as other different surfaces. Alternatively, the data communication cable 100 may be sewed or stitched into the fabric material of the garment.

In the foregoing detailed description, embodiments of the present invention in relation to a data communication cable 100 are described with reference to the provided figures. The description of the various embodiments herein is not intended to call out or be limited only to specific or particular representations of the present invention, but merely to illustrate non-limiting examples of the present invention. The present invention serves to address at least one of the mentioned problems and issues associated with the prior art. Although only some embodiments of the present invention are disclosed herein, it will be apparent to a person having ordinary skill in the art in view of this invention that a variety of changes and/or modifications can be made to the disclosed embodiments without departing from the scope of the present invention. Therefore, the scope of the invention as well as the scope of the following claims is not limited to embodiments described herein.

1. A data communication cable comprising:
a set of elongated bodies each formed from an elastic material and having an unextended free length; and
for each elongated body, a set of conductive wires disposed along the elongated body, such that each conductive wire is extendable to more than the free length of the elongated body,
wherein at least one conductive wire is configured for communicating data between electronic devices; and
wherein the conductive wires are extendable in response to extension of the elongated body, such that the extended data communication cable remains useable for said data communication between the electronic devices.

2. The data communication cable according to claim 1, wherein the data communication cable comprises two or more elongated bodies adjacently joined together along their respective longitudinal edges.

3. The data communication cable according to claim 2, wherein the elongated bodies are foldable along the longitudinal edges for the data communication cable to have a thin form factor.

4. The data communication cable according to claim 1, wherein each elongated body with the conductive wires is configured for performing one or more functions, the functions comprising high speed data transfer, low speed data transfer, and power transmission.

5. The data communication cable according to claim 1, wherein the elastic material is an elastic fabric material.

6. The data communication cable according to claim 1, wherein the conductive wires are arranged parallel to one another.

7. The data communication cable according to claim 1, wherein the conductive wires are arranged sinusoidally along the respective elongated body.

8. The data communication cable according to claim 7, wherein each cycle of the sinusoidal arrangement is stitched to the elongated body by two or four yarn loops.

9. The data communication cable according to claim 1, wherein the conductive wires wound around yarns of the respective elongated body.

10. The data communication cable according to claim 1, wherein each conductive wire comprises a coating formed from conductive yarns.

11. The data communication cable according to claim 1, further comprising an exterior shielding layer formed from an elastic material comprising conductive yarns.

12. The data communication cable according to claim 1, further comprising at least one data interface connector connected to one or both ends of the elongated bodies.

13. A method of making a data communication cable, the method comprising:
forming a set of elongated bodies from an elastic material, each elongated body having an unextended free length; and
disposing, for each elongated body, a set of conductive wires along the elongated body, such that each conductive wire is extendable to more than the free length of the elongated body,
wherein at least one conductive wire is configured for communicating data between electronic devices; and
wherein the conductive wires are extendable in response to extension of the elongated body, such that the extended data communication cable remains useable for said data communication between the electronic devices.

14. The method according to claim 13, wherein the conductive wires are disposed along the respective elongated body during or after said forming of the elongated body.

15. The method according to claim 13, wherein said disposing of the conductive wires along the respective elongated body comprises arranging the conductive wires sinusoidally along the elongated body.

16. The method according to claim 15, wherein said arranging comprises stitching each cycle of the sinusoidal arrangement to the elongated body by two or four yarn loops.

17. The method according to claim 13, wherein said disposing of the conductive wires along the respective elongated body comprises winding the conductive wires around yarns of the elongated body.

18. The method according to claim 13, wherein the elastic material is an elastic fabric material.

19. The method according to claim 13, further comprising joining the elongated bodies together along their respective longitudinal edges such that the elongated bodies are foldable along the longitudinal edges.

20. The method according to claim 13, further comprising forming an exterior shielding layer from an elastic material comprising conductive yarns for each elongated body, such that the conductive wires are interposed between the respective elongated body and the exterior shielding layer.
